(19) United States
(12) Patent Application Publication
(10) Pub. No.: US 2022/0066249 A1
(43) Pub. Date: Mar. 3, 2022

(54) DISPLAY PANEL AND ELECTRONIC DEVICE

(71) Applicant: Wuhan China Star Optoelectronics Technology Co., Ltd., Wuhan (CN)

(72) Inventor: Bingkun YIN, Wuhan (CN)

(21) Appl. No.: 16/488,593

(22) PCT Filed: May 28, 2019
(86) PCT No.: PCT/CN2019/088693

§ 371 Date: Aug. 25, 2019

(30) Foreign Application Priority Data
Mar. 29, 2019 (CN) 201910248108.5

(51) Int. Cl. G02F 1/1368; H01L 27/32

(52) U.S. Cl. CPC G02F 1/1368; H01L 27/3244

(57) ABSTRACT

A display panel and an electronic device. The display panel includes a substrate, the substrate comprising a first surface and a second surface parallel to a light emitting surface of the display panel; a thin film transistor layer disposed on the first surface, and an area of the thin film transistor layer is larger than an area of the substrate; a pixel layer disposed on the thin film transistor layer; wherein the first surface is connected to the second surface by at least one curved connecting surface to form at least one curved end of the substrate; the thin film transistor layer is bent against the at least one curved end to the second surface.

### BACKGROUND OF INVENTION

### Field of Invention

The present invention relates to the field of display technologies, and in particular, to a display panel and an electronic device.

### Description of Prior Art

In order to reduce a frame width of a liquid crystal display panel and increase a screen ratio of the display panel, a technical method commonly used in the prior art is to fold a thin film transistor layer of a non-display area of the display panel. As shown in FIG. 1, a thin film transistor layer 22 including a control chip and a gate driver on array (GOA) circuit is folded along an edge of a backlight structure 10, thereby a control circuit of the non-display area is disposed on a side of the display panel and a backlight surface and a space of a light emitting surface of the display panel will not be occupied.

### Technical Problem

Because an angle between the light emitting surface and the side surface of the backlight panel 10 is 90 degrees, the angle of the thin film transistor layer 20 is also 90 degrees. This shape will cause a large stress at bending region and cause the metal traces of the thin film transistor layer to break or the inorganic film to peel off, which will make the display panel cannot work normally.

### SUMMARY OF INVENTION

The present invention provides a display panel and an electronic device to reduce stress in a bending region of the display panel.

In order to solve the above problems, the present invention provides a display panel, wherein the display panel comprises:

a substrate, the substrate comprising a first surface and a second surface parallel to a light emitting surface of the display panel;

a thin film transistor layer disposed on the first surface, and an area of the thin film transistor layer is larger than an area of the substrate;

a pixel layer disposed on the thin film transistor layer;

wherein the first surface is connected to the second surface by at least one curved connecting surface to form at least one curved end of the substrate; the thin film transistor layer is bent against the at least one curved end to the second surface; wherein the display panel is a liquid crystal display panel;

wherein the substrate comprises a backlight structure, the first surface is a light emitting surface of the backlight structure, and the pixel layer comprises a liquid crystal layer and a color film layer on the liquid crystal layer;

or the display panel is an OLED display panel; wherein the pixel layer comprises an OLED light emitting structure.

According to one aspect of the invention, wherein the at least one curved connecting surface comprises:

a first curved surface extending from a boundary of the first surface to a center line of the first surface and the second surface; and

a second curved surface extending from a boundary of the second surface to a center line of the first surface and the second surface.

According to one aspect of the invention, wherein ends of the first curved surface and the second curved surface overlap to form the curved connecting surface;

a cut surface of the first curved surface at the overlap coincides with a cut surface of the second curved surface; and

a cut surface of the curved connecting surface at the overlap is perpendicular to the light emitting surface of the display panel.

According to one aspect of the invention, wherein the curved connecting surface further comprises a side surface;

a boundary of the side surface is connected to an end of the first curved surface, and a cut surface of the first curved surface at the connection overlaps with the side surface; and

another boundary of the side surface is connected to an end of the second curved surface, and a cut surface of the second curved surface at the connection overlaps with the side surface.

According to one aspect of the invention, wherein a horizontal cut surface of the first curved surface overlaps with the first surface.

According to one aspect of the invention, wherein the display panel further comprises an optical film between the substrate and the thin film transistor layer;

wherein a horizontal cut surface of the first curved surface is higher than the first surface and overlaps with a light emitting surface of the optical film.

According to one aspect of the invention, wherein the first curved surface and the second curved surface are axisymmetric along a center line of the first surface and the second surface.

The present invention further provides a display panel, wherein the display panel comprises:

a substrate, the substrate comprising a first surface and a second surface parallel to a light emitting surface of the display panel;

a thin film transistor layer disposed on the first surface, and an area of the thin film transistor layer is larger than an area of the substrate;

a pixel layer disposed on the thin film transistor layer;

wherein the first surface is connected to the second surface by at least one curved connecting surface to form at least one curved end of the substrate; the thin film transistor layer is bent against the at least one curved end to the second surface.

According to one aspect of the invention, wherein the at least one curved connecting surface comprises:

a first curved surface extending from a boundary of the first surface to a center line of the first surface and the second surface; and

a second curved surface extending from a boundary of the second surface to a center line of the first surface and the second surface.

According to one aspect of the invention, wherein ends of the first curved surface and the second curved surface overlap to form the curved connecting surface;

a cut surface of the first curved surface at the overlap coincides with a cut surface of the second curved surface; and

a cut surface of the curved connecting surface at the overlap is perpendicular to the light emitting surface of the display panel.

According to one aspect of the invention, wherein the curved connecting surface further comprises a side surface;

a boundary of the side surface is connected to an end of the first curved surface, and a cut surface of the first curved surface at the connection overlaps with the side surface; and

another boundary of the side surface is connected to an end of the second curved surface, and a cut surface of the second curved surface at the connection overlaps with the side surface.

According to one aspect of the invention, wherein a horizontal cut surface of the first curved surface overlaps with the first surface.

According to one aspect of the invention, wherein the display panel further comprises an optical film between the substrate and the thin film transistor layer;

wherein a horizontal cut surface of the first curved surface is higher than the first surface and overlaps with a light emitting surface of the optical film.

According to one aspect of the invention, wherein the first curved surface and the second curved surface are axisymmetric along a center line of the first surface and the second surface.

According to one aspect of the invention, wherein the display panel is an OLED display panel; wherein the pixel layer comprises an OLED light emitting structure.

According to one aspect of the invention, wherein the display panel is a liquid crystal display panel; wherein the substrate comprises a backlight structure, the first surface is a light emitting surface of the backlight structure, and the pixel layer comprises a liquid crystal layer and a color film layer on the liquid crystal layer.

The present invention further provides an electronic device, wherein the electronic device comprises a display panel, the display panel comprising:

a substrate, the substrate comprising a first surface and a second surface parallel to a light emitting surface of the display panel;

a thin film transistor layer disposed on the first surface, and an area of the thin film transistor layer is larger than an area of the substrate;

a pixel layer disposed on the thin film transistor layer;

wherein the first surface is connected to the second surface by at least one curved connecting surface to form at least one curved end of the substrate; the thin film transistor layer is bent against the at least one curved end to the second surface.

### Beneficial Effect

At least one edge of a backlight structure of a liquid crystal display panel of the present invention is provided with an arc-shaped corner protruding outward. A side surface of the backlight structure and a light emitting surface are connected by a smooth arc corner. The thin film transistor layer on the backlight structure is bent along the arc-shaped corner to the back surface of the light emitting surface of the backlight structure. The arc-shaped corner effectively reduces the stress at bending region and avoids display failure problems caused by excessive bending strength.

### BRIEF DESCRIPTION OF DRAWINGS

FIG. 1 is a structural diagram of a display panel in the prior art.

FIG. 2 is a structural diagram of a display panel in an embodiment of the present invention.

FIG. 3 is a partial enlarged structural diagram of a backlight structure of FIG. 2.

FIG. 4 is a structural diagram of a display panel in another embodiment of the present invention.

FIG. 5 is a partially enlarged schematic diagram of the backlight structure of FIG. 4.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

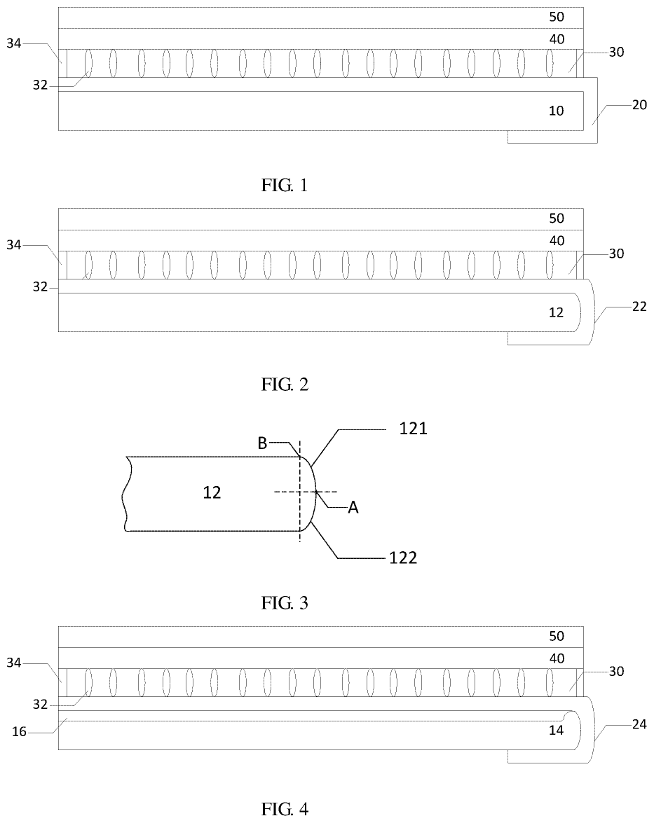

First, the prior art will be briefly described. Referring to FIG. 1, FIG. 1 is a structural diagram of a display panel in the prior art. The display panel in FIG. 1 is a liquid crystal display panel. Referring to FIG. 1, the display panel of the prior art includes a substrate 10, a thin film transistor layer 20, a pixel layer 30, an encapsulation layer 40, and a cap plate 50. Because an angle between the light emitting surface and the side surface of the backlight panel 10 is 90 degrees, the angle of the thin film transistor layer 20 is also 90 degrees. This shape will cause a large stress at bending region and cause the metal traces of the thin film transistor layer 20 breaking or the inorganic film peeling off, which will make the display panel cannot work normally.

The present invention provides a display panel and an electronic device to reduce stress in a bending region of the display panel. Referring to FIG. 2 and FIG. 3, FIG. 2 is a structural diagram of a display panel in an embodiment of the present invention, FIG. 3 is a partial enlarged structural diagram of a backlight structure of FIG. 2. The display panel includes a substrate 12, a thin film transistor layer 22, a pixel layer 30, an encapsulation layer 40, and a covering plate 50.

The substrate 12 includes a first surface and a second surface that are parallel to a light emitting surface of the display panel. In this embodiment, the display panel is a liquid crystal panel. The substrate 12 includes a backlight structure. A light emitting surface of the substrate 12 is a first surface. In other embodiments of the present invention, the display panel can be an OLED display panel. Because the substrate 12 of the liquid crystal display panel is provided with the backlight structure and a thickness thereof is generally larger than that of the OLED display panel, thereby an influence of a bending stress of a liquid crystal panel is more serious. Therefore, a liquid crystal panel is taken as an example in the embodiment. It should be emphasized that the technical solution of the present invention can also be applied to OLED display panels or other types of display panels.

The thin film transistor layer 22 is located on the first surface, and an area of the thin film transistor layer is larger than an area of the substrate 12. The thin film transistor layer 22 includes a display area control circuit directly above the first surface of the substrate 12 and a non-display area control circuit covering a side surface and a portion of the second surface of the substrate 12.

The pixel layer 30 is located on the thin film transistor layer 22. In this embodiment, the pixel layer 30 includes a liquid crystal layer and a color film layer covering the liquid crystal layer. In other embodiments, if the display panel is an OLED display panel, the pixel layer 30 is an OLED light emitting layer.

In the present invention, referring to FIG. 2, the first surface is connected to the second surface by at least one curved connecting surface to form at least one curved end of the substrate 12. The thin film transistor layer 22 is bent against the at least one curved end to the second surface.

Referring to FIG. 3, the curved connecting surface includes a first curved surface 121 and a second curved surface 122. The first curved surface 121 extending from a boundary of the first surface to a center line of the first surface and the second surface. The second curved surface 122 extending from a boundary of the second surface to a center line of the first surface and the second surface. Ends of the first curved surface and the second curved surface overlap to form the curved connecting surface.

In the present embodiment, a cut surface of the first curved surface at the overlap coincides with a cut surface of the second curved surface. A cut surface of the curved connecting surface at the overlap is perpendicular to the light emitting surface of the display panel. Preferably, referring to FIG. 3, the first curved surface 121 and the second curved surface 122 are axisymmetric along a median line of the first surface and the second surface.

In other embodiments of the present invention, considering the thickness of the substrate 12, the curved connecting surface further comprises a side surface. A boundary of the side surface is connected to an end of the first curved surface 121, and a cut surface of the first curved surface 121 at the connection overlaps with the side surface. Another boundary of the side surface is connected to an end of the second curved surface 122, and a cut surface of the second curved surface 122 at the connection overlaps with the side surface.

In this embodiment, the thin film transistor layer 22 is in direct contact with the substrate 12 to ensure that a horizontal cut surface of the thin film transistor layer 22 overlaps with the first curved surface. At this time, a horizontal cut surface of the thin film transistor layer 22 and the first curved surface (the cut surface of the first curved surface 121 at point B) overlaps with the first surface.

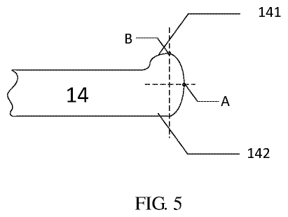

In other embodiments, other thin films are further included between the thin film transistor layer 22 and the substrate 12. As shown in FIG. 4 and FIG. 5, FIG. 4 is a structural diagram of a display panel in another embodiment of the present invention, FIG. 5 is a partially enlarged schematic diagram of the backlight structure of FIG. 4. In FIG. 4, a polarizer 16 is further disposed between the thin film transistor layer 24 and the substrate 14. The thin film transistor layer 24 is in direct contact with the polarizer 16. At this time, if the structures of the first curved surface 141 and the second curved surface 142 connecting the substrate 14 are the same as those in FIG. 3, there would be a gap between the thin film transistor layer 24 and the substrate 14, which cannot be closely adhered. Thereby the film transistor layer 24 is caused to have poor pressure resistance and is easily broken at the gap, resulting in the display failure in the panel.

Therefore, in order to ensure that the thin film transistor layer 24 and the side surface of the substrate 14 are seamlessly bonded, a horizontal cut surface (cut surface at point B) of the first curved surface 141 is higher than the first surface, and overlaps with the light emitting surface of the polarizer 16. Preferably, referring to FIG. 4, the first curved surface 141 and the second curved surface 142 are asymmetrically disposed along a median line of the first surface and the second surface.

Referring to FIG. 4, this arrangement can ensure that the thin film transistor layer 24 and the side surface of the substrate 14 are seamlessly bonded to prevent a gap from being formed at the bending corner to reduce the pressure resistance of the thin film transistor layer 24.

The present invention further provides an electronic device, wherein the electronic device comprises a display panel described above.

At least one edge of a backlight structure of a liquid crystal display panel of the present invention is provided with an arc-shaped corner protruding outward. A side surface of the backlight structure and a light emitting surface are connected by a smooth arc corner. The thin film transistor layer on the backlight structure is bent along the arc-shaped corner to the back surface of the light emitting surface of the backlight structure. The arc-shaped corner effectively reduces the stress at bending region and avoids display failure problems caused by excessive bending strength.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A display panel, wherein the display panel comprises:
a substrate, the substrate comprising a first surface and a second surface parallel to a light emitting surface of the display panel;
a thin film transistor layer disposed on the first surface, and an area of the thin film transistor layer is larger than an area of the substrate;
a pixel layer disposed on the thin film transistor layer;
wherein the first surface is connected to the second surface by at least one curved connecting surface to form at least one curved end of the substrate; the thin film transistor layer is bent against the at least one curved end to the second surface; wherein the display panel is a liquid crystal display panel;
wherein the substrate comprises a backlight structure, the first surface is a light emitting surface of the backlight structure, and the pixel layer comprises a liquid crystal layer and a color film layer on the liquid crystal layer.

2. The display panel according to claim 1, wherein the at least one curved connecting surface comprises:
a first curved surface extending from a boundary of the first surface to a center line of the first surface and the second surface; and
a second curved surface extending from a boundary of the second surface to a center line of the first surface and the second surface.

3. The display panel according to claim 2, wherein ends of the first curved surface and the second curved surface overlap to form the curved connecting surface;
a cut surface of the first curved surface at the overlap coincides with a cut surface of the second curved surface; and
a cut surface of the curved connecting surface at the overlap is perpendicular to the light emitting surface of the display panel.

4. The display panel according to claim 2, wherein the curved connecting surface further comprises a side surface;
a boundary of the side surface is connected to an end of the first curved surface, and a cut surface of the first curved surface at the connection overlaps with the side surface; and
another boundary of the side surface is connected to an end of the second curved surface, and a cut surface of the second curved surface at the connection overlaps with the side surface.

5. The display panel according to claim 2, wherein a horizontal cut surface of the first curved surface overlaps with the first surface.

6. The display panel according to claim 2, wherein the display panel further comprises an optical film between the substrate and the thin film transistor layer;
wherein a horizontal cut surface of the first curved surface is higher than the first surface and overlaps with a light emitting surface of the optical film.

7. The display panel according to claim 2, wherein the first curved surface and the second curved surface are axisymmetric along a center line of the first surface and the second surface.

8. A display panel, wherein the display panel comprises:
a substrate, the substrate comprising a first surface and a second surface parallel to a light emitting surface of the display panel;
a thin film transistor layer disposed on the first surface, and an area of the thin film transistor layer is larger than an area of the substrate;
a pixel layer disposed on the thin film transistor layer;
wherein the first surface is connected to the second surface by at least one curved connecting surface to form at least one curved end of the substrate; the thin film transistor layer is bent against the at least one curved end to the second surface.

9. The display panel according to claim 8, wherein the at least one curved connecting surface comprises:
a first curved surface extending from a boundary of the first surface to a center line of the first surface and the second surface; and
a second curved surface extending from a boundary of the second surface to a center line of the first surface and the second surface.

10. The display panel according to claim 9, wherein ends of the first curved surface and the second curved surface overlap to form the curved connecting surface;
a cut surface of the first curved surface at the overlap coincides with a cut surface of the second curved surface; and
a cut surface of the curved connecting surface at the overlap is perpendicular to the light emitting surface of the display panel.

11. The display panel according to claim 9, wherein the curved connecting surface further comprises a side surface;
a boundary of the side surface is connected to an end of the first curved surface, and a cut surface of the first curved surface at the connection overlaps with the side surface; and
another boundary of the side surface is connected to an end of the second curved surface, and a cut surface of the second curved surface at the connection overlaps with the side surface.

12. The display panel according to claim 9, wherein a horizontal cut surface of the first curved surface overlaps with the first surface.

13. The display panel according to claim 9, wherein the display panel further comprises an optical film between the substrate and the thin film transistor layer;
wherein a horizontal cut surface of the first curved surface is higher than the first surface and overlaps with a light emitting surface of the optical film.

14. The display panel according to claim 9, wherein the first curved surface and the second curved surface are axisymmetric along a center line of the first surface and the second surface.

15. The display panel according to claim 8, wherein the display panel is an OLED display panel; wherein the pixel layer comprises an OLED light emitting structure.

16. The display panel according to claim 8, wherein the display panel is a liquid crystal display panel; wherein the substrate comprises a backlight structure, the first surface is a light emitting surface of the backlight structure, and the pixel layer comprises a liquid crystal layer and a color film layer on the liquid crystal layer.

17. An electronic device, wherein the electronic device comprises a display panel, the display panel comprising:
a substrate, the substrate comprising a first surface and a second surface parallel to a light emitting surface of the display panel;
a thin film transistor layer disposed on the first surface, and an area of the thin film transistor layer is larger than an area of the substrate;
a pixel layer disposed on the thin film transistor layer;
wherein the first surface is connected to the second surface by at least one curved connecting surface to form at least one curved end of the substrate; the thin film transistor layer is bent against the at least one curved end to the second surface.
